(19) United States
(12) Patent Application Publication
(10) Pub. No.: US 2026/0122814 A1
(43) Pub. Date: Apr. 30, 2026

(54) CONDUCTIVE POLYMER ENHANCED SOCKET

(71) Applicant: Advanced Micro Devices, Inc., Santa Clara, CA (US)

(72) Inventors: Layne Albert BERGE, Fort Collins, CO (US); Scotty NEALLY, Santa Clara, CA (US); Cameron Robert REFAEE, Santa Clara, CA (US); Dean GONZALES, Fort Collins, CO (US); Srikant NEKKANTY, Austin, TX (US); Datta Sandesh MANJUNATH, Santa Clara, CA (US)

(21) Appl. No.: 18/932,330

(22) Filed: Oct. 30, 2024

(51) Int. Cl. H05K 7/10; G01R 1/04; H01R 12/71; H05K 1/02; H05K 1/18

(52) U.S. Cl. CPC H05K 7/1069; G01R 1/0466; H01R 12/714; H05K 1/0245; H05K 1/181; H05K 2201/10325

(57) ABSTRACT

Disclosed herein are a socket, an electronic device having a socket, and methods for communicating between a printed circuity board (PCB) and an integrated circuity (IC) die through a socket. In one example, a socket is provided that includes a base plate, a ground connector coupled to the base plate, and a plurality of electrical signal connectors coupled to the base plate. A first electrical signal connector of the plurality of electrical signal connectors includes an IC chip contact portion extending above the base plate, and a board contact portion extending below the base plate. The ground connector includes an IC chip ground pad contact portion extending above the base plate. The IC chip contact portion is formed from a polymer that is conductive and/or coated by a conductive material.

### TECHNICAL FIELD

Embodiments of the present disclosure generally relate to a socket having a ground connection enhanced by a conductive polymer; an electronic devices having an integrated circuit (IC) die coupled to a printed circuit board (PCB) by a socket having a ground connection enhanced by a conductive polymer, and techniques for communicating between an IC die and a PCB using a socket having a ground connection enhanced by a conductive polymer.

### BACKGROUND

High speed signaling is fundamental to all data center and AI/ML applications today. Reliable coherent chip to chip communication and low-latency memory access is essential for scale up/scale out of generative AI, as well as the mainstream modular datacenter (MDC) server markets.

Data center reliability and serviceability (RAS) requirements are increasingly challenged as data rates increase, and data center OPEX (operating expense) is driven lower. Today, LAN grid array (SMLGA) sockets that are surface mounted to printed circuit boards (PCB) are used to allow for the field replacement of integrated circuit (IC) dies that include microprocessors and/or ASICs. While the ability to replace IC dies is invaluable for reliability and serviceability, the socket self-parasitics are a limiting performance factor. The electrically long mechanical cantilever springs of the SMLGA socket are designed to be mechanically robust and have enough mechanical movement to absorb the organic package substrate warpage and PCB coplanarity. The high SMLGA spring count present in a single modern processor requires hundreds of pounds of compression force (i.e., in excess of 400 lbf) to ensure all signal, ground and power pins are actuated fully. However, this high compression force undesirably creates new deflection and reliability issues. For example, conventional SMLGA sockets have good performance up to 30 GHz, but above which artifacts from the long pins become susceptible to undesirable crosstalk.

Thus, there is a need for an improved socket for coupling an IC die to a printed circuit board.

### SUMMARY

Disclosed herein are a socket, an electronic device having a socket, and methods for communicating between a printed circuity board (PCB) and an integrated circuity (IC) die through a socket. In one example, a socket is provided that includes a base plate, a ground connector coupled to the base plate, and a plurality of electrical signal connectors coupled to the base plate. A first electrical signal connector of the plurality of electrical signal connectors includes an IC chip contact portion extending above the base plate, and a board contact portion extending below the base plate. The ground connector includes an IC chip ground pad contact portion extending above the base plate. The IC chip contact portion is formed from a polymer that is conductive and/or coated by a conductive material.

In another example, a socket is provided that includes a base plate; a plurality of electrical signal connectors coupled to the base plate, and a ground connector coupled to the base plate. A first electrical signal connector and a second electric connector of the plurality of electrical signal connectors each including an IC chip signal pad contact portion extending above the base plate, and a board contact portion extending below the base plate. The ground connector includes ground plane layer having apertures through which the electrical signal connectors extend.

In some examples, the ground connector of the socket includes an IC chip contact portion extending upwards from the ground plane layer away from the base plate. The IC chip ground pad contact portion including an electrically conductive material.

In some examples, the electrically conductive material is a conductive polymer, or a conductive material coating a polymeric core.

In yet another example, electronic device is provided that includes a printed circuity board (PCB), a socket mounted to the PCB, and an integrated circuity (IC) die electrically connected to the PCB through the socket. The socket includes IC chip ground pad contact portion comprised of a conductive polymer or a polymer at least partially coated with a conductive material. The conductive material provides a ground path connecting functional circuitry of the IC die with ground circuitry of the PCB.

In still another example, a method for communicating between a printed circuity board (PCB) and an integrated circuity (IC) die through a socket is provided. The method includes transmitting data signals between circuitry of the PCB and functional circuitry of the IC die through signal connectors of the socket; and grounding the functional circuitry of the IC die to circuitry of the PCB through a ground connector of the socket, the ground connector at least partially fabricated from a polymer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a perspective top view of an integrated circuit (IC) die being loaded into a socket mounted to a printed circuit board (PCB), the IC die, socket and PCB forming an electronic device.

FIG. 2 is a perspective bottom view of the IC die depicted FIG. 1.

FIG. 3 is a schematic top view of a portion of the socket depicted in FIG. 1.

FIG. 4 is a schematic partial sectional view of the socket depicted in FIG. 1.

FIG. 5 is a schematic partial sectional view of the socket depicted in FIG. 1 shown between and spaced apart from a bottom surface of the IC die and the top surface of the PCB.

FIGS. 6-10 are partial schematic sectional views of different examples of the socket.

FIGS. 11-13 are partial schematic top views of different examples of the socket.

FIG. 14 is a side view of one example of an electronic device having a socket.

FIG. 15 is a flow diagram of one example of a method for communicating between a printed circuity board (PCB) and an integrated circuity (IC) die through a socket.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Embodiments of the disclosure generally provide a conductive polymer enhanced socket, along with electronic devices and methods for communicating between a printed circuity board (PCB) and an integrated circuity (IC) die through the socket. The novel conductive polymer enhanced socket uses a conductive polymer as part of the ground circuitry formed through the socket. The conductive polymer may be a conductive polymer or a combination of a core formed from a polymeric material that is at least partially covered by a conductive layer. By providing ground connections through a polymer connector as opposed to convention cantilevered spring ground connections, the amount of force required to ensure good electrical connection between the IC die and the PCB is dramatically reduced. The large rejection in force contributes to less warpage, and consequently increase reliability. The polymer based ground connections provide increased conductively with diminished propensity for undesirable crosstalk, consequently creating an environment amenable to deep microwave signaling (i.e., transmission speeds in excess of 100 Gbps). The use of polymer based ground connections within the socket additionally enables field replacement of IC dies, along with reduced costs.

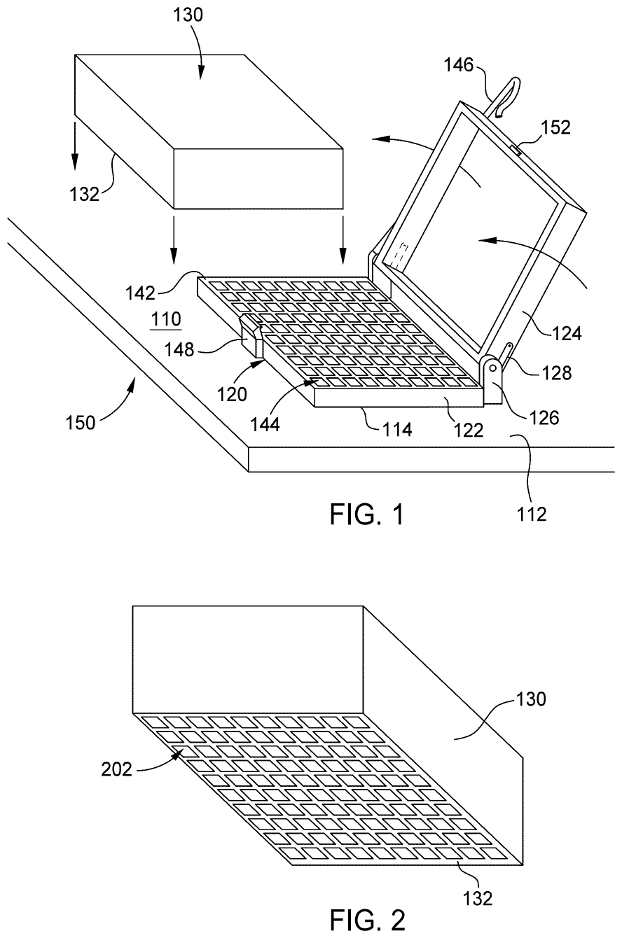

Turning first to FIG. 1, a perspective top view of an integrated circuit (IC) die 130 being loaded into a socket 120 mounted to a printed circuit board (PCB) 110 are shown. An electronic device 150 is formed once the IC die 130 is secured in the socket 120, thus electrically connecting functional circuitry of the IC die 130 and the circuitry of the PCB 110.

The socket 120 has a base plate 122 and a clamp frame 124. The base plate 122 is coupled to the clamp frame 124 by a hinge 126. The base plate 122 and the clamp frame 124 are generally fabricated or coated by a non-conductive material, such as a dielectric polymer. In one example, the base plate 122 and/or the clamp frame 124 may be fabricated from and/or coated with polyaryletherketone (PEEK), liquid crystal polymer (LCP), polyetherimide (PEI), polyamide-imide (PAI) or other suitable non-electrically conductive material. The hinge 126 may also include a spring 128 that applies a rotational bias to the clamp frame 124 about the hinge 126. The base plate 122 and clamp frame 124 may also include a latch 148 and catch 152 configured to secure the base plate 122 and clamp frame 124 in a closed position. In the closed position, the clamp frame 124 urges a bottom surface 132 of the IC die 130 against a top surface 142 of the base plate 122. The socket 120 may also include a clamp bar 146 for applying a force that urges the bottom surface 132 of the IC die 130 against the top surface 142 of the base plate 122 with sufficient force that ensures good electrical connection between the IC die 130 and the socket 120.

The top surface 142 of the base plate 122 include a plurality of electrical signal connectors 144. The electrical signal connectors 144 are configured to connect the contact pads 202 (shown on the bottom side 132 of the IC die 130 depicted in FIG. 2) with the circuitry of the PCB 110. The electrical signal connectors 144 are generally configured as spring pins such that the downward force applied by the clamp frame 124 to the IC die 102 urges the contact pads 202 against the electrical signal connectors 144 with sufficient force to ensure good electrical connection is established between the IC die 130 and the PCB 110 through electrical signal connectors 144 of the socket 120. The deflection of the electrical signal connectors 144 generally accommodates non-parallelism between the top surface 142 of the base plate 122 of the socket 120 and the bottom surface 132 of the IC die 130. The electrical signal connectors 144 are generally arranged in an X/Y array. Some of the electrical signal connectors 144 may be utilized as power delivery routing. Although not illustrated in FIG. 1, ground connectors are disposed on the top surface 142 of the base plate 122 adjacent at least some of the electrical signal connectors 144 of the socket 120.

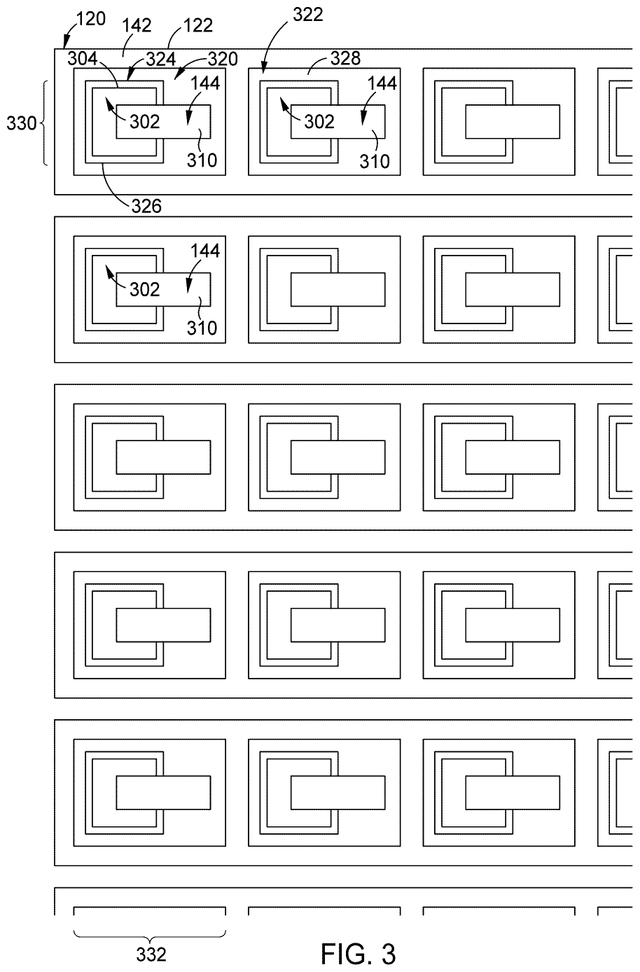

FIG. 3 is a schematic top view of a portion of the socket 120 depicted in FIG. 1 illustrating a ground connector 320 disposed on the top surface 142 of the base plate 122 adjacent at least some of the electrical signal connectors 144. The ground connector 320 includes one or more IC chip ground pad contact portions 322 that extend upward and away from the top surface 142 of the base plate 122. The IC chip ground pad contact portion 322 is electrically conductive and configured to contact the ones of the contact pads 202 of the IC die 130 that are part of the ground circuit of the IC die 130. The ground connector 320 is also coupled to the ground circuitry of the PCB 110, as later described below.

The IC chip ground pad contact portion 322 can be configured to contact a single contact pad 202 of the IC die 130. However, the IC chip ground pad contact portion 322 can be beneficially configured to contact a plurality of contact pads 202 of the IC die 130 with significantly less force than as would be exerted if convention ground spring pins were utilized.

In one example, the IC chip ground pad contact portion 322 of the ground connector 320 is configured as singular unitary grid that extends across the top surface 142 of the base plate 122. In another example, a plurality of IC chip ground pad contact portions 322 are arranged in discrete or connected rows and/or columns. In another example, a plurality of IC chip ground pad contact portions 322 are arranged in discrete or connected segments. In yet another example, a plurality of IC chip ground pad contact portions 322 are arranged in discrete or connected polyhedra, non-polyhedra and/or compound 3D shapes, such as cubes, cuboids, cylinders, partial spheres, spherical caps, hemispheres, spherical frustums, spherical segments, full and truncated pyramids, full and truncated cones, among others.

Optionally, the ground connector 320 may include a ground plane layer 328. The ground plane layer 328 is a conductive sheet disposed on the top surface 142 of the base plate 122. The IC chip ground pad contact portions 322 are connected (mechanically and electrically) to the ground plane layer 328. The IC chip ground pad contact portions 322 extend upward from the ground plane layer 328 and away from the top surface 142 of the base plate 122. In one example, the IC chip ground pad contact portions 322 and the ground plane layer 328 are a homogeneous one piece structure. In another example, the IC chip ground pad contact portions 322 and the ground plane layer 328 are separate components affixed together as an assembly. In another example, the IC chip ground pad contact portions 322 and the ground plane layer 328 are insert molded with the base plate 122. In still another example, the IC chip ground pad contact portions 322 and the ground plane layer 328 are adhered or otherwise secured to the top surface 142 of the base plate 122. Optionally, multiple discrete ground plane layers 328 may be disposed on the top surface 142 of the base plate 122.

In the example depicted in FIG. 3, conductive spring pins 310 comprising the electrical signal connectors 144 are arranged in rows 330 and columns 332. To accommodate the rows 330 and columns 332 of electrical signal connectors 144, the base plate 122 includes a plurality of apertures 302. Each of the apertures 302 accommodates at least one or more of the conductive spring pins 310 of the electrical signal connectors 144. In FIG. 3, each aperture 302 accommodates a single one of the conductive spring pins 310, and as such, the aperture 302 are also arranged in rows 330 and columns 332. In other examples, each aperture 302 may accommodate two or more conductive spring pins 310. The sidewall 304 of the aperture 302 is spaced from the electrical signal connector 144 to allow the connector 144 to move freely.

In embodiments wherein the ground connector 320 includes a ground plane layer 328 disposed on the top surface 142 of the base plate 122, the ground plane layer 328 also includes apertures 324. Each aperture 324 is separated from an adjacent aperture 324 by a web of the ground plane layer 328. Each aperture 324 of the ground plane layer 328 generally surrounds one or more of the apertures 302 formed through the base plate 122, thus enabling each conductive spring pins 310 to extend through both apertures 302, 324. The aperture 324 is generally larger than the aperture 302.

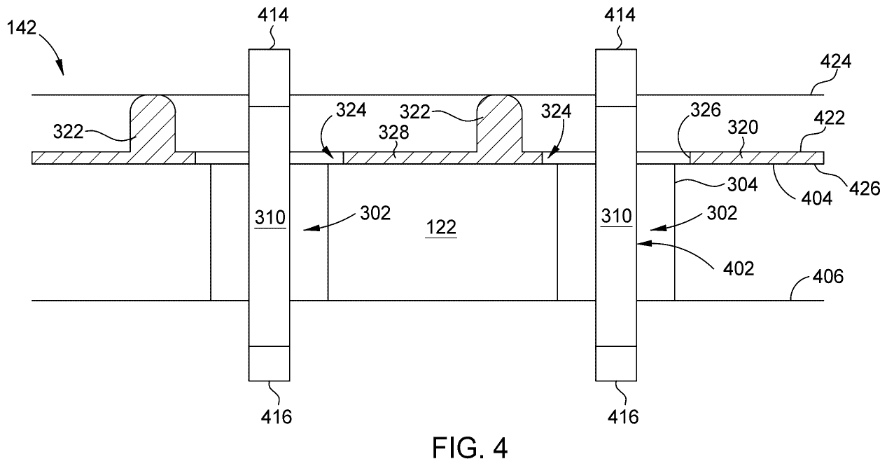

As seen more clearly in the sectional view depicted in FIG. 4, the sidewall 326 of the aperture 324 is spaced laterally outward of the sidewall 304 of the aperture 302 of the base plate 122. Thus as the sidewall 304 of the aperture 302 is closer to the side 402 of the conductive spring pin 310 than the sidewall 304 of the aperture 302, the side 402 of the conductive spring pin 310 is substantially prevented from contacting, and thus shorting to, the ground plane layer 328 of the ground connector 320. In this manner, the side 304 of the aperture 302 of the base plate 122 may be positioned very close to the side 402 of the conductive spring pin 310, thereby enabling more precise positioning of the conductive spring pin 310 along with smaller pitch spacing.

Each conductive spring pin 310 includes an IC signal pad contact portion 414 and a board pad contact portion 416. The IC signal pad contact portion 414 extends above the top surface 142 of the base plate 122. The IC signal pad contact portion 414 may optionally extends above a top surface 424 of the IC chip ground pad contact portion 322. The IC signal pad contact portion 414 is generally flexible to allow the IC signal pad contact portion 414 to deflect upon coming in contact with the contact pad 202 of the IC die 130 when the IC die 130 is clamped in the socket 120.

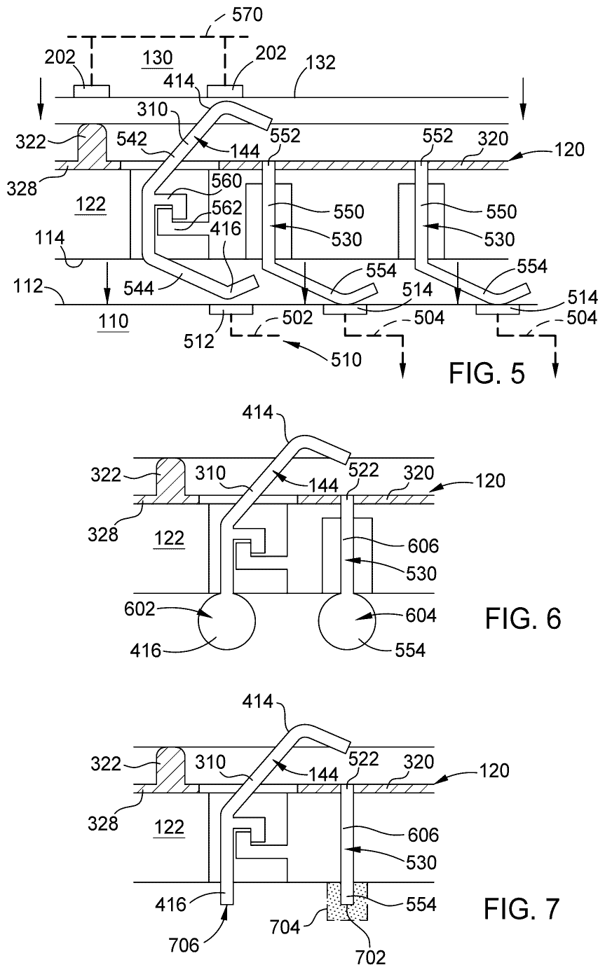

The board pad contact portion 416 extends below a bottom surface 406 of the base plate 122. The board pad contact portion 416 is generally configured to provide good electrical contact with the contact pads of the PCB 110. Various non-limiting examples of the board pad contact portion 416 are later provided below with reference to FIGS. 5-7.

Continuing to refer to the example depicted in FIG. 4, the ground plane layer 328 of the ground connector 320 is generally a planar sheet of material. The ground plane layer 328 includes a top surface 422 and a bottom surface 426. The bottom surface 426 is disposed on a top surface 404 of the base plate 122. The bottom surface 426 of the ground plane layer 328 may be secured to the top surface 404 of the base plate 122 using a pressure sensitive or other type of adhesive. The ground plane layer 328 may alternatively be secured to the top surface 404 of the base plate 122 using other techniques.

In the example depicted in FIG. 4, the ground pad contact portion 322 extends from the top surface 422 of the ground plane layer 328 in a direction away from the base plate 122. The ground pad contact portion 322 may have any suitable sectional shape, as discussed above.

FIG. 5 is a schematic partial sectional view of the socket 120 depicted in FIG. 1 shown between and spaced apart from the bottom surface 132 of the IC die 130 and the top surface 112 of the PCB 110. Although not shown, the socket 120 may be secured to the top surface 112 of the PCB 110 by fasteners, clamps, adhesive, solder or other suitable technique.

The conductive spring pin 310 is illustrated in greater detail in FIG. 5. The conductive spring pin 310 is generally fabricated from an electrically conductive flexible material. In one example, the conductive spring pin 310 includes an upper spring arm 542, a catch 560, and and a lower spring arm 544. The catch 560 is disposed between the upper and lower spring arms 542, 544. The catch 560 is configured to secure the conductive spring pin 310 to the base plate 122. In the example depicted in FIG. 5, the catch 560 of the conductive spring pin 310 is configured to engage with a complimentary shaped lip 562 extending from the base plate 122 into the aperture 302. Alternatively, the conductive spring pin 310 may be secured to the base plate 122 through other techniques.

The upper spring arm 542 of the conductive spring pin 310 generally extends from the catch 560 and terminates at the IC signal pad contact portion 414. The upper spring arm 542 flexes as the IC die 130 is installed into the socket 120 such that the IC signal pad contact portion 414 is urged into good electrical contact with the signal contact pad 202 of the IC die 130. The IC signal pad contact portion 414 thus connects the conductive spring pin 310 with the functional circuitry 570 of the IC die 130.

The lower spring arm 544 of the conductive spring pin 310 generally extends from the catch 560 and terminates at the board pad contact portion 416. The lower spring arm 544 flexes as the socket 120 is secured to the PCB 110 such that the board pad contact portion 416 is urged into good electrical contact with the board signal contact pad 512 exposed on the top surface 112 of the PCB 110. The pad contact portion 416 thus connects the conductive spring pin 310 with the board routing circuitry 510, and particularly the signal routing circuitry 502 of the PCB 110. Thus, after the socket 120 is secured to the PCB 110 and the IC die 130 is clamped in the socket 120, the signal routing circuitry 502 of the PCB 110 is coupled to the functional circuitry 570 of the IC die 130 through the conductive spring pin 310. Power may optionally be routed through the conductive spring pins 310 in a similar manner between power supply pads/routing of the PCB 110 to the power supply network of the functional circuitry 570 of the IC die 130.

The IC chip ground pad contact portion 322 of the ground connector 320 also contacts the ground contact pads 202 of the IC die 130 when the IC die 130 is installed into the socket 120. The IC chip ground pad contact portion 322 couples the ground circuitry within the functional circuitry 570 of the IC die 130 to ground through the PCB 110. The IC chip ground pad contact portion 322 is coupled to ground contact pads 514 of the PCB 110 via a ground connector 530. The ground connector 530 is fabricated from an electrically conducting material, such as copper, aluminum, stainless steel, and the like. The ground connector 530 has connecting rod 550 that includes a termination end 552 and a pad contact portion 554. The connecting rod 550 is generally secured to the base plate 122.

The termination end 552 is coupled to the ground plane layer 328 in a manner that enables good electrical communication therebetween. The ground plane layer 328 connects the ground connector 530 to the IC chip ground pad contact portion 322. In the example depicted in FIG. 5, as plurality of ground connector 530 couple the ground plane layer 328 to the PCB 110. Although only two ground connectors 530 are shown in FIG. 5, any desirable number of ground connectors 530 may be utilized. Alternatively, one or more ground connectors 530 may be directly connected to the IC chip ground pad contact portion 322, for example but not limited to embodiments where the ground plane layer 328 is not present.

The ground connector 530 terminates a pad contact portion 554. The pad contact portion 554 may be configured similar to the lower spring arm 544 and the board pad contact portion 416 of the conductive spring pin 310 described above. The pad contact portion 554 is urged into good electrical contact with the ground contact pad 514 of the PCB 110 upon mounting the socket 120 to the PCB 110. The ground contact pad 514 of the PCB 110 is coupled to the ground routing circuitry 504 that is part of the board routing circuitry 510 of the PCB 110. Thus, the ground connector 530 enables the functional circuitry 570 of the IC die 130 to be coupled to the ground routing circuitry 504 of the PCB 110 when the IC die 130 is clamped into the socket 120.

FIGS. 6 and 7 provide various, non-limiting alternatives to the board pad contact portion 416 of the conductive spring pin 310 and the pad contact portion 554 of the ground connector 530 of the socket 120. Referring first to FIG. 6, the board pad contact portion 416 of the conductive spring pin 310 is shown as a solder ball 602. The solder ball 602 may be reflowed to mechanically and electrically connect the board pad contact portion 416 of the conductive spring pin 310 to the contact pad 512 of the PCB 110 (as shown in FIG. 5). As similarly illustrated in FIG. 6, the pad contact portion 554 of the ground connector 530 is shown as a solder ball 604. The solder ball 604 may be reflowed to mechanically and electrically connect the pad contact portion 554 of the ground connector 530 to the ground contact pad 514 of the PCB 110 (as shown in FIG. 5).

In FIG. 7, the board pad contact portion 416 of the conductive spring pin 310 is shown as a pin 706. The pin 706 may be a pogo pin, straight pin or other suitable connector. The pin 706 may be pressed against the contact pad 512 or inserted into a hole (formed in the PCB 110 in lieu of the contact pad 512) to mechanically and electrically connect the board pad contact portion 416 (i.e., the pin 706) of the conductive spring pin 310 to the signal routing circuitry 502 of the PCB 110 (as shown in FIG. 5). As similarly illustrated in FIG. 6, the pad contact portion 554 of the ground connector 530 is shown as a pin 702. The pin 706 may be may be pressed against the contact pad 514 or inserted into a hole (formed in lieu of the contact pad 514) to mechanically and electrically connect the pad contact portion 554 (i.e., the pin 702) of the ground connector 530 to the ground routing circuitry 504 of the PCB 110 (as shown in FIG. 5). Alternatively, the pad contact portion 554 of the ground connector 530 may terminate at a conductive polymer connector 704. The conductive polymer connector 704 is generally configured similar to the IC chip ground pad contact portion 322 as described herein.

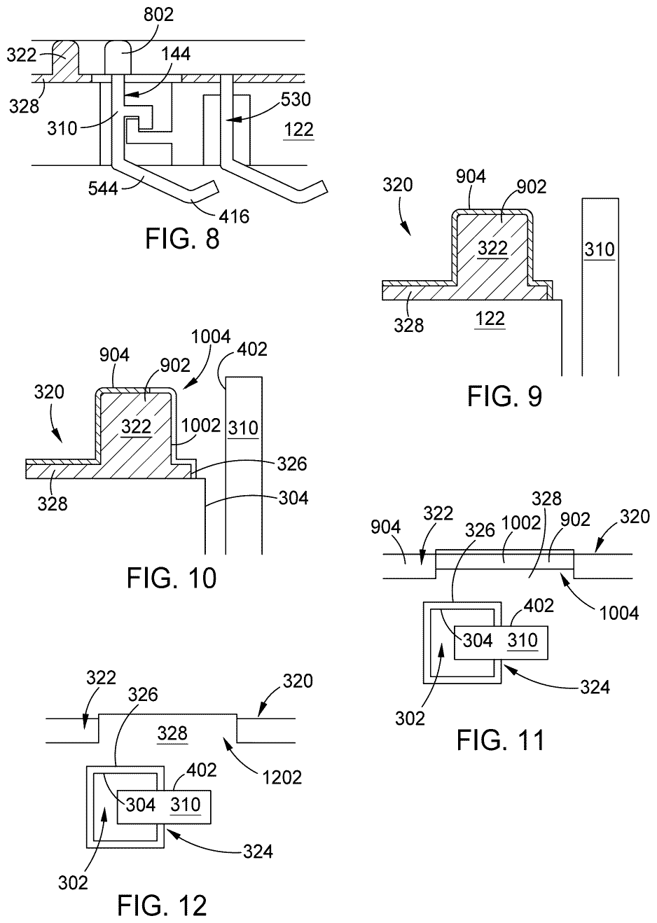

FIG. 8 is a schematic sectional view of a portion of the socket 120 depicted in FIG. 1 illustrating another example of the conductive spring pin 310 comprising the electrical signal connectors 144. The conductive spring pin 310 may be configured similar to any of the examples depicted above, except in that the upper spring arm 542 is replaced by a compliant conductive button 802. The conductive button 802 may be comprises of metal wire, metal mesh or metal foam. In one example, the conductive button 802 is comprised of gold-plated beryllium copper wire compressed into a dense, sponge-like cylindrical shape. Alternatively, the conductive button 802 may be made from other types of conductive metals, and/or have a non-cylindrical shape.

Although in FIG. 8 the compliant conductive button 802 is shown as the IC signal pad contact portion 414 of the conductive spring pin 310, the compliant conductive button 802 may alternatively or in addition be utilized as the board pad contact portion 416 of the conductive spring pin 310 and/or the pad contact portion 554 of the ground connector 530.

As discussed above, at least the IC chip ground pad contact portion 322 of the ground connector 320 is fabricated from and/or is coated by a flexible electrically conductive polymer material. Suitable conductive polymer materials include polyaniline, intrinsically conducting polymers (ICPs), polyaniline (PANI), polypyrrole (PPy), poly(3,4-ethylenedioxythiophene):polystyrenesulfonate (PEDOT:PSS), polythiophene (PTP), and polymer nanocomposites having conductive carbon-based nano-/microstructures such as CNT, carbon fiber, graphene, graphene oxide, and carbon black as fillers. Carbon-based fillers can be easily dispersed in a polymer matrix, producing an electrically conductive network. The ground plane layer 328 may be made from the same material as the IC chip ground pad contact portion 322. In one example, the ground plane layer 328 and the IC chip ground pad contact portion 322 are formed as a homogeneous single piece component, such as insert molded with the base plate 122.

Alternatively as depicted in FIG. 9, the IC chip ground pad contact portion 322 of the ground connector 320 is fabricated from a polymeric base 902 having an electrically conductive exterior layer 904. The polymeric base 902 is generally a resilient polymer or elastomer. The polymeric base 902 may be not electrically conductive. The electrically conductive exterior layer 904 is disposed on the polymeric base 902. The electrically conductive exterior layer 904 may be a conductive polymer, such as described above, or may be a conductive film such as metal plating. In one example, the electrically conductive exterior layer 904 is comprises of copper plating.

The ground plane layer 328 may be also made from the same material as the IC chip ground pad contact portion 322, i.e., a polymeric base 902 having an electrically conductive exterior layer 904.

In some examples, the electrically conductive exterior layer 904 may be removed from or not deposited on a portion of the ground connector 320, such as depicted in FIGS. 10 and 11. In the example depicted in FIGS. 10 and 11, the electrically conductive exterior layer 904 is not present on a portion (e.g., exposed portion 1002) of the polymeric base 902 comprising the portion of the ground plane layer 328 that is located immediately adjacent the side 402 of the conductive spring pin 310, thus reducing potential for shorting while also beneficially enabling tighter pitch and increased density of the conductive spring pins 310.

Optionally, the electrically conductive exterior layer 904 may be absent from a portion of the IC chip ground pad contact portion 322 such that the exposed portion 1002 of the polymeric base 902 extends along the side of the IC chip ground pad contact portion 322 that faces the side 402 of the conductive spring pin 310. The exposed portion 1002 of the polymeric base 902 may optionally even include at least a portion of the top surface of the IC chip ground pad contact portion 322 closest the side 402 of the conductive spring pin 310.

FIG. 12 depicts a top view of a portion of the IC chip ground pad contact portion 322 adjacent the side 402 of the conductive spring pin 310. In the example depicted in FIG. 12, the IC chip ground pad contact portion 322 may be comprised of a conductive polymer, or alternatively be comprised of a polymeric base 902 coated with an electrically conductive exterior layer 904. In the example depicted in FIG. 12, the portion of the IC chip ground pad contact portion 322 adjacent the side 402 of the conductive spring pin 310 includes a notch 1202. The notch 1202 provides additional space between the IC chip ground pad contact portion 322 and the side 402 of the conductive spring pin 310, thus reducing potential for shorting while also beneficially enabling tighter pitch and increased density of the conductive spring pins 310.

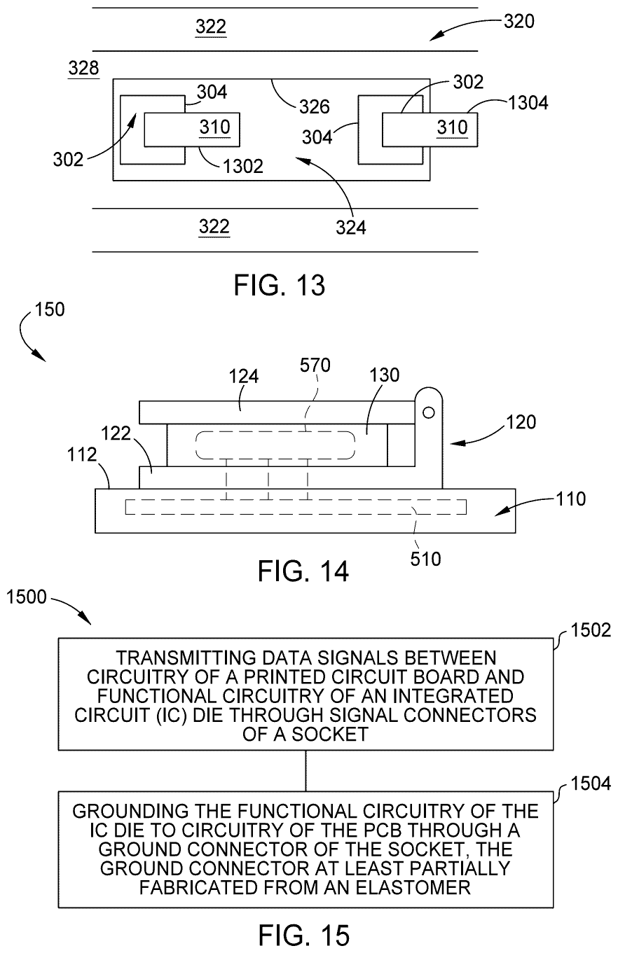

FIG. 13 depicts another top view of a portion of socket 120 illustrating at least two or more conductive spring pins 310 extending through a single aperture 324 of the ground plane layer 328 of the ground connector 320. In the example depicted in FIG. 13, the two conductive spring pins 310, shown as conductor 1302 and conductor 1304, are a differential pair of signal conductors. The conductors 1302, 1304 are configured to transmit complementary signals in opposite polarity but of equal magnitude. As the ground plane layer 328 surrounds and separates the conductors 1302, 1304 from other differential pairs and power conductors, signal transmission is improved due to reduced noise and increased headroom.

FIG. 14 is a schematic side view of the electronic device 150 originally depicted in FIG. 1. The electronic device 150 includes the IC die 130 installed in the socket 120 that is mounted to the PCB 110. In the electronic device 150, the functional circuitry 570 of the IC die 130 is electrically connected to the board routing circuitry 510 of the PCB 110 through the socket 120.

FIG. 15 is a flow diagram of a method 1500 for communicating between a printed circuity board (PCB) and an integrated circuity (IC) die through a socket, such as the PCB 110, IC die 130, and socket 120 described above, among others. The method 1500 begins at operation 1502 by transmitting data signals between circuitry of the PCB and functional circuitry of the IC die through signal connectors of the socket. Optionally, operation 1502 may include transmitting a differential pair of data signals through a common aperture formed in the ground connector.

At operation 1504, the ground of the functional circuitry of the IC die is connected to the circuitry of the PCB through a ground connector of the socket. The ground connector at least partially fabricated from a polymer. The polymer may be a conductive polymer, or a core fabricated from a polymer material that is coated with a conductive material, such as a plated metal layer or conductive polymer. Optionally, operation 1504 may include contacting multiple ground connections exposed on a bottom surface of the IC with the ground connector.

In addition to the examples described above, the disclosed technology may also be expressed in the following non-limiting examples.
Example 1. A socket including: a base plate; a plurality of electrical signal connectors coupled to the base plate, a first electrical signal connector of the plurality of electrical signal connectors including: an IC chip contact portion extending above the base plate; and a board contact portion extending below the base plate; and a ground connector coupled to the base plate, the ground connector including: an IC chip contact portion extending above the base plate, the IC chip contact portion comprised of a polymer; and a first board contact portion extending below the base plate.
Example 2. The socket of Example 1, wherein the IC chip contact portion of the ground connector further includes a conductive polymer.
Example 3. The socket of Example 2, wherein the conductive polymer is polyaniline, intrinsically conducting polymers (ICPs), polyaniline (PANI), polypyrrole (PPy), poly(3,4-ethylenedioxythiophene):polystyrenesulfonate (PEDOT:PSS), and polythiophene (PTP), polymer nanocomposites having carbon-based nano-/microstructures such as CNT, carbon fiber, graphene, graphene oxide, and carbon black as fillers. Carbon-based fillers can be easily dispersed in a polymer matrix, producing an electrically conductive network.
Example 4. The socket of Example 1, wherein the IC chip contact portion of the ground connector further includes: a polymeric base having an electrically conductive exterior layer.
Example 5. The socket of Example 4, wherein the conductive exterior layer is a layer of metal plating.
Example 6. The socket of Example 5, wherein the polymeric base is closer to the first electrical signal connector than the layer of metal plating.
Example 7. The socket of Example 1, wherein the first board contact portion of the ground connector further includes a conductive polymer, a solder ball, or a spring form.
Example 8. The socket of Example 1, wherein the ground connector includes: a ground plane layer that is disposed over the base plate, the IC chip contact portion of the ground connector extending upwards from the ground plane layer away from the base plate.
Example 9. The socket of Example 8, wherein the ground plane further includes: a first aperture formed through the ground plane, the first electrical signal connector extending through the first aperture.
Example 10. The socket of Example 9 further including: a second electrical signal connector of the plurality of electrical signal connectors extending through the first aperture, the first and second electrical signal connectors configured to transmit a differential pair of signals.
Example 11. The socket of Example 9 further including: a second electrical signal connector of the plurality of electrical signal connectors extending through a second aperture formed through the ground plane, the first and second apertures separated by a web of the ground plane.
Example 12. The socket of Example 9, wherein the IC chip contact portion of the ground connector is cutaway directly adjacent the first aperture.
Example 13. The socket of Example 1, wherein the IC chip contact portion of the ground connector is coupled to the first board contact portion and a second board contact portion, the second board contact portion extending below the base plate.
Example 14. A socket including: a base plate; a plurality of electrical signal connectors coupled to the base plate, a first electrical signal connector and a second electric connector of the plurality of electrical signal connectors each including: an IC chip contact portion extending above the base plate; and a board contact portion extending below the base plate; and a ground connector coupled to the base plate, the ground connector including: a ground plane layer that is disposed over the base plate, the ground plane having apertures through which the electrical signal connectors extend; and IC chip contact portion of the ground connector extending upwards from the ground plane layer away from the base plate, the IC chip contact portion including an electrically conductive material.
Example 15. The socket of Example 14, wherein the IC chip contact portion of the ground connector further includes a conductive polymer.
Example 16. The socket of Example 14, wherein the IC chip contact portion of the ground connector further includes: a polymeric base having an electrically conductive exterior layer.
Example 17. The socket of Example 14, wherein the IC chip contact portions of two electrical signal connectors extend through a common one of the apertures, the first and second electrical signal connectors configured to transmit a differential pair of signals.
Example 18. A method for communicating between a printed circuity board (PCB) and an integrated circuity (IC) die through a socket, the method including: transmitting data signals between circuitry of the PCB and functional circuitry of the IC die through signal connectors of the socket; and grounding the functional circuitry of the IC die to circuitry of the PCB through a ground connector of the socket, the ground connector at least partially fabricated from a polymer.
Example 19. The method of Example18, wherein transmitting data signals between the circuitry of the PCB and the functional circuitry of the IC die through signal connectors of the socket further includes: transmitting a differential pair of data signals through a common aperture formed in the ground connector.
Example 20. The method of Example18, wherein grounding the functional circuitry of the IC die to circuitry of the PCB through a ground connector of the socket further includes: contacting multiple ground connections exposed on a bottom surface of the IC with the ground connector.
Example 21. An electronic device including a printed circuity board (PCB); a socket mounted to the PCB; and an integrated circuity (IC) die electrically connected to the PCB through the socket, wherein an IC chip contact portion is formed from a conductive polymer or a polymer at least partially coated with a conductive material, the conductive material providing a ground path connecting functional circuitry of the IC die with ground circuitry of the PCB.

Thus, a conductive polymer enhanced socket has been disclosed above, along with electronic devices and methods for communicating between a printed circuity board (PCB) and an integrated circuity (IC) die through the socket. The socket uses a conductive polymer as part of the ground circuitry formed through the socket to beneficially reduce the spring force required to seat the IC die within the socket while maintaining reliable electrical connection. The reduced spring force also beneficially reduces the amount of warpage, which improves the reliability and service life. The polymer based ground connections also provide increased conductively with a diminished propensity for undesirable crosstalk, consequently creating an environment amenable to deep microwave signaling (i.e., transmission speeds in excess of 100 Gbps). The use of polymer based ground connections within the socket additionally enables field replacement of IC dies, along with reduced costs.

What is claimed is:

1. A socket comprising:
a base plate;
a plurality of electrical signal connectors coupled to the base plate, a first electrical signal connector of the plurality of electrical signal connectors comprising:
an IC chip signal pad contact portion extending above the base plate; and
a board contact portion extending below the base plate; and
a ground connector coupled to the base plate, the ground connector comprising:
an IC chip ground pad contact portion extending above the base plate, the IC chip contact portion comprised of a polymer.

2. The socket of claim 1, wherein the IC chip ground pad contact portion of the ground connector further comprises a conductive polymer.

3. The socket of claim 2, wherein the conductive polymer is polyaniline, intrinsically conducting polymers (ICPs), polyaniline (PANI), polypyrrole (PPy), poly(3,4-ethylenedioxythiophene):polystyrenesulfonate (PEDOT:PSS), and polythiophene (PTP), polymer nanocomposites having carbon-based nano-/microstructures such as CNT, carbon fiber, graphene, graphene oxide, and carbon black as fillers. Carbon-based fillers can be easily dispersed in a polymer matrix, producing an electrically conductive network.

4. The socket of claim 1, wherein the IC chip ground pad contact portion of the ground connector further comprises: a polymeric base having an electrically conductive exterior layer.

5. The socket of claim 4, wherein the conductive exterior layer is a layer of metal plating.

6. The socket of claim 5, wherein a portion of the polymeric base adjacent to the first electrical signal connector is exposed through the layer of metal plating.

7. The socket of claim 1, wherein ground connector further comprises:
a first board contact portion coupled to the IC chip ground pad contact portion, the first board contact portion comprising a conductive polymer, a solder ball, or a spring form.

8. The socket of claim 1, wherein the ground connector comprises:
a ground plane layer disposed over the base plate, the IC chip ground pad contact portion of the ground connector extending upwards from the ground plane layer away from the base plate.

9. The socket of claim 8, wherein the ground plane layer further comprises:
a first aperture formed through the ground plane layer, the first electrical signal connector extending through the first aperture.

10. The socket of claim 9 further comprising:
a second electrical signal connector of the plurality of electrical signal connectors extending through the first aperture, the first and second electrical signal connectors configured to transmit a differential pair of signals.

11. The socket of claim 9 further comprising:
a second electrical signal connector of the plurality of electrical signal connectors extending through a second aperture formed through the ground plane layer, the first and second apertures separated by a web of the ground plane layer.

12. The socket of claim 9, wherein the IC chip ground pad contact portion of the ground connector has a notch disposed directly adjacent the first aperture.

13. The socket of claim 1, wherein the IC chip ground pad contact portion of the ground connector is coupled to a plurality of board ground contact portions extending below the base plate.

14. An electronic device comprising:
a printed circuity board (PCB);
a socket mounted to the PCB; and
an integrated circuity (IC) die electrically connected to the PCB through the socket, wherein an IC chip ground pad contact portion of a ground connector of the socket is formed from a conductive polymer or a polymer at least partially coated with a conductive material, the conductive material providing a ground path connecting functional circuitry of the IC die with ground circuitry of the PCB.

15. The electronic device of claim 14, wherein the socket further comprises:
a base plate;
a plurality of electrical signal connectors coupled to the base plate, a first electrical signal connector and a second electrical signal connector of the plurality of electrical signal connectors each comprising:
an IC chip signal pad contact portion extending above the base plate;
a board signal pad contact portion extending below the base plate; and wherein the ground connector is coupled to the base plate, the ground connector comprising:
a ground plane layer that is disposed over the base plate, the ground plane layer having apertures through which the electrical signal connectors extend; and
one or more IC chip ground pad contact portions extending upwards from the ground plane layer away from the base plate.

16. The electronic device of claim 14, wherein the IC chip ground pad contact portion of the ground connector further comprises: a polymeric base having an electrically conductive exterior layer.

17. The electronic device of claim 15, wherein the IC chip signal pad contact portions of two electrical signal connectors extend through a common one of the apertures, the two electrical signal connectors configured to transmit a differential pair of signals.

18. A method for communicating between a printed circuity board (PCB) and an integrated circuity (IC) die through a socket, the method comprising:
transmitting data signals between circuitry of the PCB and functional circuitry of the IC die through signal connectors of the socket; and
grounding the functional circuitry of the IC die to the circuitry of the PCB through a ground connector of the socket, the ground connector at least partially fabricated from a polymer.

19. The method of claim 18, wherein transmitting data signals between the circuitry of the PCB and the functional circuitry of the IC die through signal connectors of the socket further comprises:
transmitting a differential pair of data signals through a common aperture formed in the ground connector.

20. The method of claim 18, wherein grounding the functional circuitry of the IC die to circuitry of the PCB through a ground connector of the socket further comprises:
contacting multiple ground connections exposed on a bottom surface of the IC with the ground connector.
